(19) United States
(12) Patent Application Publication
(10) Pub. No.: US 2024/0424685 A1
(43) Pub. Date: Dec. 26, 2024

(54) SUBSTRATE SAFETY SYSTEM

(71) Applicant: Applled Materials lsrael Ltd., Rehovot (IL)

(72) Inventors: Binyamin Bejell, Rehovot (IL); Itamar Orenbuch, Rehovot (IL); Avi Aboodi, Rehovot (IL)

(73) Assignee: Applied Materials lsrael Ltd., Rehovot (IL)

(21) Appl. No.: 18/214,435

(22) Filed: Jun. 26, 2023

(51) Int. Cl. B25J 11/00; B25J 9/16; B25J 13/08

(52) U.S. Cl. CPC B25J 11/0095; B25J 9/163; B25J 9/1653; B25J 13/08

(57) ABSTRACT

A substrate safety system that includes (i) a control unit that is configured to trigger a substrate recovery related procedure; (ii) a sensing unit that is configured to generate, during an execution of the substrate recovery related procedure, sensed information that is indicative of one or more regions that are associated with a substrate handling station of a substrate evaluation system; (iii) an AI processing unit that is configured to apply an AI process on the sensed information to determine a recovery related status of the substrate; and (iv) a response unit that is configured to respond to the recovery related status of the substrate.

### BACKGROUND OF THE INVENTION

A substrate may be evaluated by a substrate evaluation system such as a charged particle substrate evaluation system. A charged particle substrate evaluation system is configured to evaluate the substrate by illuminating the substrate by one or more charged particle beams.

Examples of substrate evaluation systems include (i) defect review systems such as a defect review scanning electron microscope SEMVISION™ of APPLIED MATERIALS™ Inc. of San Jose, California, (ii) a metrology system such as the PROVision™ 3E Ebeam™ metrology system of APPLIED MATERIALS™, (iii) an electron beam inspection system such as the PRIMEVISION™ of APPLIED MATERIALS™, or (iv) a critical dimension scanning electron microscope such as the VERITYSEM™ of APPLIED MATERIALS™, and the like. The charge particle evaluation system may manufactured by vendors such as HITACHI™ of Tokyo, Japan, or KLA™ Corporation of Milpitas, California, or may be manufactured by other vendors.

The illuminating the substrate by the one or more charged particle beams requires to position the substrate within a vacuum chamber.

A substrate evaluation system includes one or more vacuum chambers and also includes one or more interfaces for receiving a substrate from a non-vacuum environment.

The substrate evaluation system includes one or more substrate handling stations for moving the substrate to a vacuum chamber, for moving the substrate from a vacuum chamber, moving the substrate between vacuum chambers, moving the substrate from a vacuum chamber to a non-vacuum environment, moving the substrate from a non-vacuum environment to a vacuum chamber, and the like.

An emergency substrate recovery process may be triggered when there is an ambiguity about the location of the substrate. For example—when the location of the substrate according to a software monitor determines that the substrate is located at a first location—while a hardware monitor determines that the substrate is located at the second location that differs from the first location.

A human operator may be required to manually control the position of the substrate within the substrate evaluation system—and even to manually control the unloading of the substrate from the substrate evaluation system, during an emergency substrate recovery process.

The human operator may damage the substrate and even break the substrate when manually controlling the position of the substrate.

It has been found that the emergency substrate recovery process may be triggered by error.

There is a growing need to reduce the risk imposed to the substrate by the manual control of the position of the substrate within the substrate evaluation system.

### SUMMARY

There is provided a substrate safety system that includes (a) a control unit that is configured to trigger a substrate recovery related procedure; (b) a sensing unit that is configured to generate, during the substrate recovery related procedure, sensed information that is indicative of one or more regions that are associated with a substrate handling station of a substrate evaluation system; (c) an artificial intelligence (AI) processing unit that is configured to apply an AI process on the sensed information to determine a recovery related status of the substrate; and (d) a response unit that is configured to respond to the recovery related status of the substrate.

There is provided a method for enhancing a safety of a substrate, the method includes: (a) triggering, by a control unit, a substrate recovery related procedure; (b) generating, by a sensing unit and during the substrate recovery related procedure, sensed information that is indicative of one or more regions that are associated with a substrate handling station of a substrate evaluation system; (c) applying, by an artificial intelligence (AI) processing unit, an AI process on the sensed information to determine a recovery related status of the substrate; and (d) responding to the recovery related status of the substrate by a response unit.

There is provided a non-transitory computer readable medium for enhancing a safety of a substrate, the non-transitory computer readable medium stores instructions that once executed by substrate safety system, cause the substrate safety system to: (a) trigger, by a control unit of the substrate safety system, a substrate recovery related procedure; (b) generate, by a sensing unit and during the substrate recovery related procedure, sensed information that is indicative of one or more regions that are associated with a substrate handling station of a substrate evaluation system; (c) apply, by an artificial intelligence (AI) processing unit of the substrate safety system, an AI process on the sensed information to determine a recovery related status of the substrate; and (d) respond to the recovery related status of the substrate by a response unit of the substrate safety system.

### BRIEF DESCRIPTION OF THE DRAWINGS

The subject matter regarded as the invention is particularly pointed out and distinctly claimed in the concluding portion of the specification. The invention, however, both as to organization and method of operation, together with specimens, features, and advantages thereof, may best be understood by reference to the following detailed description when read with the accompanying drawings in which:

FIG. 1 illustrates an example of a substrate safety system;

FIG. 2 illustrates an example of a substrate safety system, and also illustrates a cross section of a substrate evaluation system;

FIG. 3 illustrates examples of a substrate, a substrate handling station, a first illumination element, a second illumination element, a first sensing element, and a second sensing element;

FIG. 4 illustrates an example of a method for enhancing a safety of a substrate;

FIG. 5 illustrates an example of a substrate safety system; and

FIG. 6 illustrates an example of a method for enhancing a safety of a substrate.

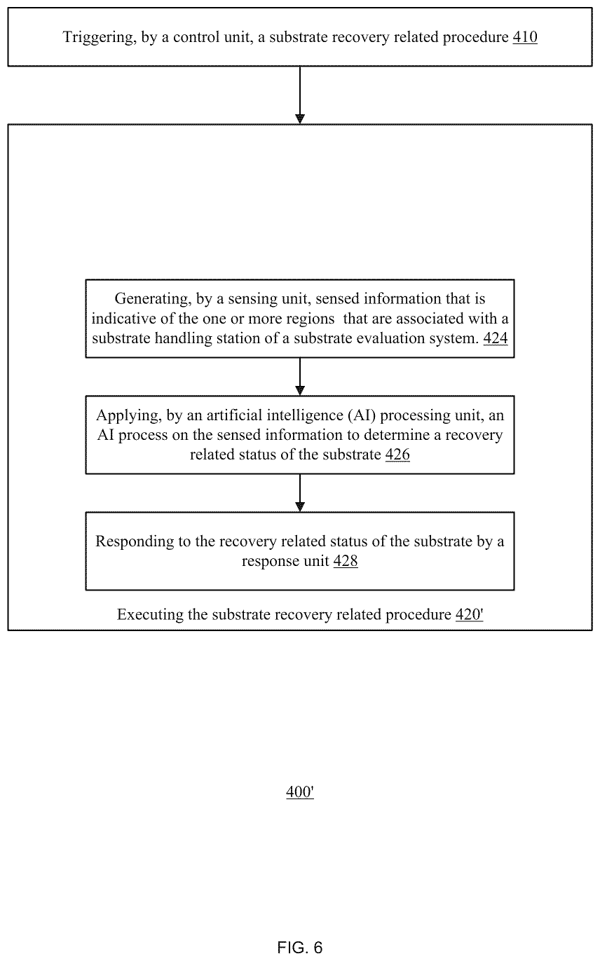

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DRAWINGS

In the following detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a system capable of executing the method and should be applied mutatis mutandis to a computer program product that stores instructions that once executed result in the execution of the method.

Any reference in the specification to a system should be applied mutatis mutandis to a method that may be executed by the system and should be applied mutatis mutandis to a computer program product that stores instructions that can be executed by the system.

Any reference in the specification to a computer program product should be applied mutatis mutandis to a method that may be executed when executing instructions stored in the computer program product and should be applied mutandis to a system that is configured to executing instructions stored in the computer program product.

The term “and/or” means additionally or alternatively. For example A and/or B means only A, or only B or A and B.

There may be provided a substrate safety system. The substrate safety system enhances the safety of the substrate in relation to substrate recovery, as the substrate safety system accurately determines the recovery related status of the substrate, and responds according to the recovery related status of the substrate.

The substrate may be a bare wafer, a patterned wafer, a solar panel, and the like.

The term “recovery related status of the substrate” means information about the substrate that is relevant to a recovery procedure of the substrate. Especially, the recovery related status of the substrate provides an indication of whether there is a need to recover the substrate.

According to an embodiment, the recovery related status of the substrate also provides an indication of how to recover the substrate, when the recovery of the substrate is required.

Examples of a recovery related status of the substrate may include a broken substrate, a misplaced substrate, an absent substrate, and a properly placed substrate. It should be noted that a substrate may be both broken and misplaced, broken and properly positioned, and the like.

The term “one or more regions that are associated with a substrate handling station” means one or more regions that belong to the substrate handling station or that are proximate to the substrate handling station. Proximate means within the reach of the substrate handling station. A substrate that is within the reach of the substrate handling station can be manipulated by the substrate handling station.

The one or more regions that are associated with a substrate handling station are positioned to provide an indication about the recovery related status of the substrate. For example, a region associated with the substrate handling station may be positioned downstream to the substrate (or at least downstream a part of the substrate), when the substrate is properly positioned and not broken—so that when the substrate is properly positioned and is not broken, at least a part of the region is obscured by the substrate.

The region may not be obscured by the substrate when the substrate is absent or misplaced or broken. The region may be positioned at a location in which the edge of the substrate is obscures a part of the region when the substrate is properly positioned.

There may be provided a substrate safety system that may determine the recovery related status of the substrate independently from other sources of information regarding the recovery related status of the substrate.

The independent determining of the recovery related status of the substrate is beneficial in situations in which the substrate evaluation system or any other substrate monitor malfunctions or is not trusted. Such a situation may occur when different evaluations of the location of the substrate are provided from two different entities, for example, having (i) a first substrate location estimate from a software (for example an operating system such as JAVA™ or SEMorai™) executed by the substrate evaluation system and (ii) a second substrate location estimate (that differs from the first substrate location estimate) from a hardware sensor of the substrate evaluation system.

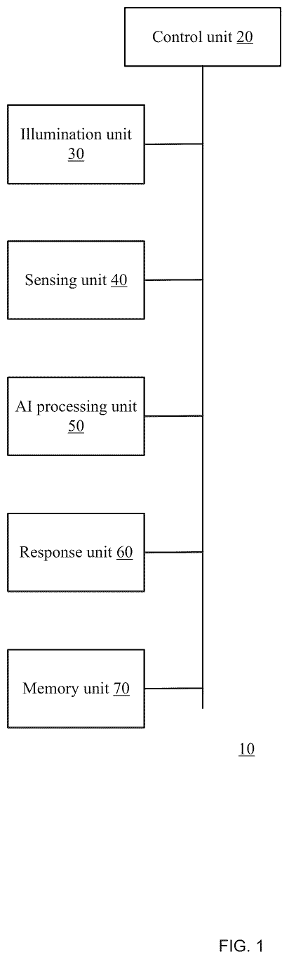

FIG. 1 illustrates an example of a substrate safety system 10 that includes: A control unit 20 that is configured to trigger a substrate recovery related procedure.

An illumination unit 30 that is configured to illuminate one or more regions that are associated with a substrate handling station of a substrate evaluation system, during an execution of the substrate recovery related procedure.

A sensing unit 40 that is configured to generate sensed information that is indicative of the one or more regions.

An artificial intelligence (AI) processing unit 50 that is configured to apply an AI process on the sensed information to determine a recovery related status of the substrate.

A response unit 60 that is configured to respond to the recovery related status of the substrate.

FIG. 1 also illustrates a memory unit 70 configured to store instructions, and additionally or alternatively, information such as sensed information.

At least one of the control unit 20, the AI processing unit 50, and the response unit 60 may include one or more processing circuits or may be implemented using one or more processing circuits. A processing circuit may be implemented as a central processing unit (CPU), and/or one or more other integrated circuits such as application-specific integrated circuits (ASICs), field programmable gate arrays (FPGAs), full-custom integrated circuits, an AI processor, etc., or a combination of such integrated circuits.

The recovery related status of the substrate may be a broken substrate, or a misplaced substrate, or an absent substrate or a properly placed substrate.

The recovery related status of the substrate may be a broken substrate, or a misplaced substrate, or an absent substrate or an existing substrate. A properly placed substrate may be classified as the existing substrate and not the misplaced substrate.

The response unit 60 may be configured to respond by at least one of the following responses:
a. Requesting an execution of a manual unloading of the substrate from the handling station.
b. Requesting an execution of a substrate evaluation system controller unloading of the substrate from the handling station.
c. Instructing an execution of a substrate evaluation system controller unloading of the substrate from the handling station.
d. Sending an indication that a recovery of the substrate is irrelevant.
e. Stop a recovery process of the substrate.
f. Provide information about the exact location of the substrate.

The AI processing unit 50 is configured to apply a classification process to determine the substrate recovery related status.

The AI processing unit 50 may have been trained to apply the classification process based on one or more coverage parameters related to a coverage of each one of the one or more regions by the substrate. A coverage parameter represent the coverage of the one or more regions by the substrate.

For example, the training may include training a convolution neural network (CNN) such as the ResNet18 neural network that was pre-trained using IMAGNET1000, has four classification heads for the four different recovery related statuses of the substrate. The CNN is tuned to data dedicated to images related to substrates of different recovery related statuses.

There may be multiple regions and the sensing unit may include a plurality of sensors. Each region may be associated with one or more sensors.

Having multiple regions, especially when there regions cover only a fraction (for example—up to 5%, 10%, 15% of the substrate) of the entire substrate, allows to concentrate the sensing and/or image processing on smaller areas—thereby simplifying the sensing unit and reducing the cost of the sensing unit.

It should be noted that the substrate safety system 10 may be used to monitor multiple substrate handling stations and not just a single substrate handling station.

For example, the substrate evaluation system may include an additional substrate handling station. The illumination unit is configured to illuminate one or more additional regions that are associated with the additional substrate handling station, during the execution of the substrate recovery related procedure. The sensing unit is configured to generate additional sensed information that is indicative of the one or more regions. The AI processing unit is configured to apply the AI process on the sensed information and on the additional sensed information to determine the recovery related status of the substrate.

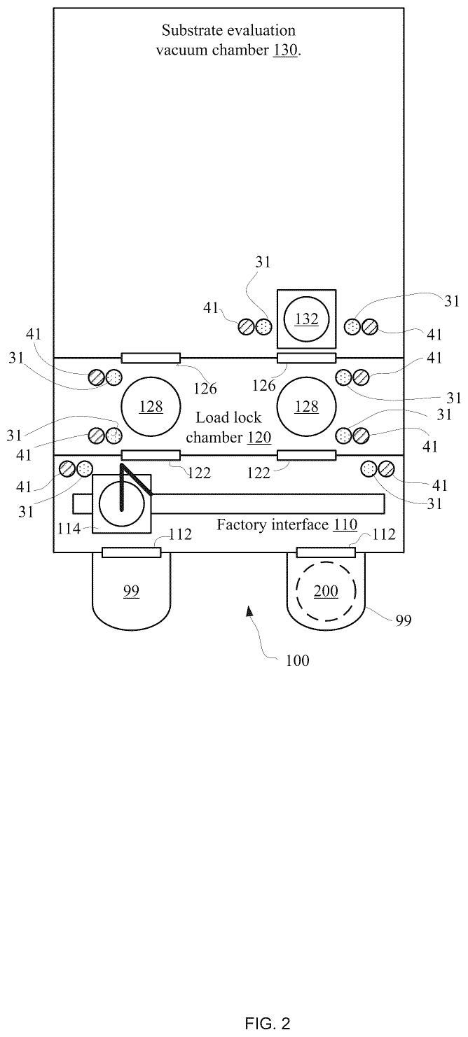

FIG. 2 illustrates an example of the substrate safety system 10 and also illustrates a cross section of a substrate evaluation system 100.

The substrate evaluation system 100 includes factory interface 110, a load lock chamber 120 and a substrate evaluation vacuum chamber 130 in which the substrate is evaluated.

The factory interface 110 can be any suitable enclosure, such as, e.g., an Equipment Front End Module (EFEM).

The factory interface 110 can be configured to receive one or more substrates from substrate carriers 99 (e.g., Front Opening Unified Pods (FOUPs)) docked at various load ports 112 of the factory interface. One of the substrate carriers 99 is illustrated as storing substrate 200.

The factory interface robot 114 is configured to transfer substrates between the substrate carriers 99 and the load lock chamber 120.

The load lock chamber 120 includes one or more slit valves and/or doors such as doors 122 configured to open when receiving or releasing substrates to and/or from factory interface robots 114.

The load lock chamber 120 includes one or more additional slit valves and/or additional doors such as additional doors 126 configured to open when receiving or releasing substrates to and/or from substrate evaluation vacuum chamber 130.

The load lock chamber includes substrate support units 128 for supporting substrates located within the load lock chamber.

A vacuum environment, a clean environment, and/or a temperature controlled environment may be maintained within the load lock chamber 120 and/or the substrate evaluation vacuum chamber 130.

The substrate evaluation vacuum chamber 130 includes a mechanical stage 132 for supporting the substrate and moving the substrate within the substrate evaluation vacuum chamber 130.

In FIG. 2, each one of the factory interface robot 114, the load lock chamber 120 and the mechanical stage 132 is regarded as a substrate handling station.

The illumination unit FIG. 2 includes eight illumination elements 31 and the sensing unit includes eight sensing elements 41. At least a pair of sensing elements and a pair of illumination elements are allocated per substrate handling station. The load lock chamber is allocated with four sensing elements 41 and four illumination elements 31.

An illumination element is a source of light such as a lamp, a light emitting diode (LED), and the like.

A sensing element is an image sensing element such as a camera.

There may be any number of illumination elements per substrate handling station, one illumination element per substrate handling station or two or more illumination elements per substrate handling station.

There may be any number of sensing elements per substrate handling station, one sensing element per substrate handling station or two or more sensing elements per substrate handling station.

Different numbers of sensing elements may be allocated to two different substrate handling stations.

The same number of sensing elements may be allocated to two different substrate handling stations.

Different numbers of illumination elements may be allocated to two different substrate handling stations.

The same number of illumination elements may be allocated to two different substrate handling stations.

In FIG. 2, the control unit 20, the AI processing unit 50 and the response unit 60 are located outside the substrate evaluation system 100.

It should be noted that the substrate safety system 10 is configured to monitor the state of one or more substrates within substrate evaluation systems that differ from the substrate evaluation system 100 of FIG. 2. The substrate evaluation systems may include any number of chambers and/or any number of components and/or units.

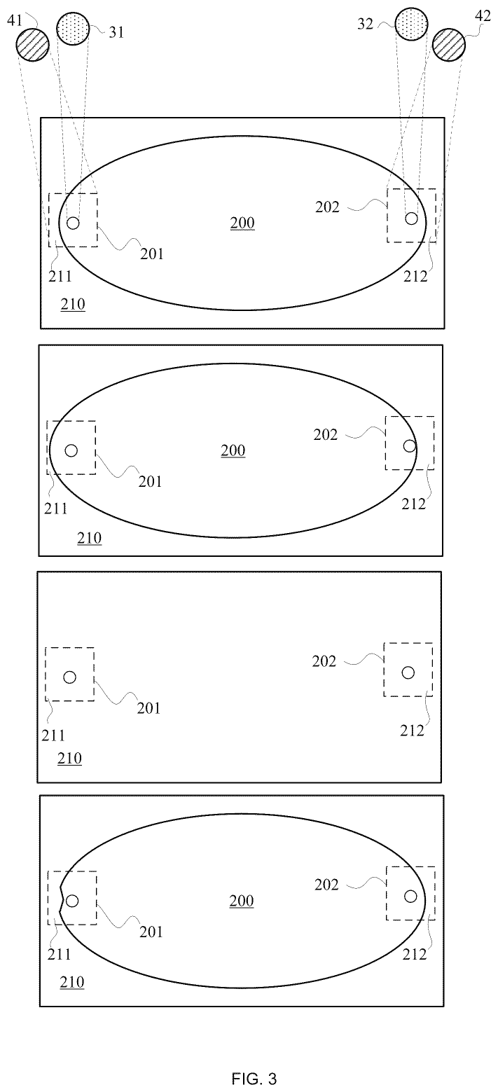

FIG. 3 illustrates examples of a substrate 200 and of a substrate handling station 210, a first illumination element 31, a second illumination element 32, a first sensing element 41 and a second sensing element 42.

The first illumination element 31 illuminates a first region 201 associated with the substrate handling station 210 and the first sensing element 41 acquires an image of the first region 201.

The second illumination element 32 illuminates a second region 202 associated with the substrate handling station 210 and the second sensing element 42 acquires an image of the second region 202.

In a first example, the substrate 200 is properly positioned on the substrate handling station 210.
a. The image of the first region 201 illustrates a first edge region of a substrate 200 that is positioned at a desired position (for example at a desired distance from the edge of the substrate handling station), and also illustrates a first portion 211 of the substrate handling station 210 that is uncovered by the substrate 200.
b. The image of the second region 202 illustrates a second edge region of a substrate 200 that is positioned at a desired position (for example at a desired distance from the edge of the substrate handling station), and also illustrates a second portion 212 of the substrate handling station 210 that is uncovered by the substrate 200.

In a second example, the substrate 200 is misplaced and is located closer to the first portion 211 of the substrate handling station.
a. The image of the first region 201 illustrates a first edge region of a substrate 200 that is misplaced (positioned at a distance that is smaller than the desired distance from the edge of the substrate handling station), and also illustrates the first portion 211 of the substrate handling station 210 that is uncovered by the substrate 200—and is smaller than the first portion 211 of the first example.
b. The image of the second region 202 illustrates a second edge region of a substrate 200 that is misplaced (positioned at a distance that exceeds the desired distance from the edge of the substrate handling station), and also illustrates a second portion 212 of the substrate handling station 210 that is uncovered by the substrate 200—and is smaller than the second portion 212 of the first example.

In a third example, the substrate 200 is absent.
a. The image of the first region 201 and the image of the second region 202 illustrate only the substrate handling station 210.

In a fourth example, the substrate 200 has a broken edge—which is captured in the image of the first region.

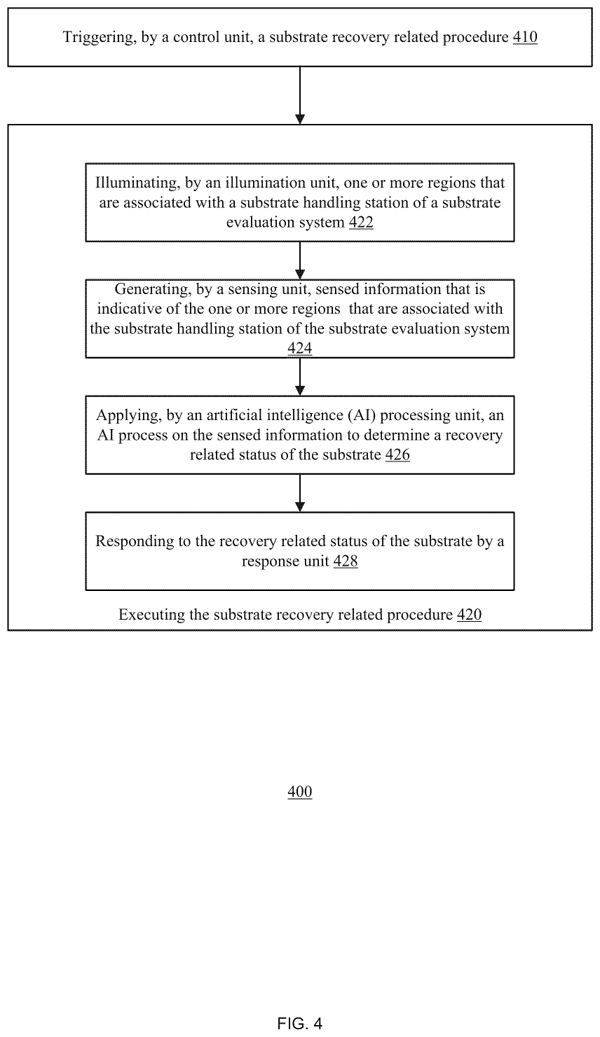

FIG. 4 illustrates an example of a method 400 for enhancing a safety of a substrate.

Method 400 may start by step 410 of triggering, by a control unit, a substrate recovery related procedure.

Step 410 is followed by step 420 of executing the substrate recovery related procedure.

Step 420 includes steps 422, 424, 426 and 428.

Step 422 includes illuminating, by an illumination unit, one or more regions that are associated with a substrate handling station of a substrate evaluation system.

Step 422 is followed by step 424 of generating, by a sensing unit, sensed information that is indicative of the one or more regions that are associated with the substrate handling station of the substrate evaluation system.

Step 424 is followed by step 426 of applying, by an artificial intelligence (AI) processing unit, an AI process on the sensed information to determine a recovery related status of the substrate.

According to an embodiment, step 426 includes applying a classification process to determine the substrate recovery related status.

According to an embodiment, the AI processing unit has been trained to apply the classification process based on one or more coverage parameters related to a coverage of each one of the one or more regions by the substrate.

According to an embodiment, the recovery related status of the substrate is selected out of a broken substrate, a misplaced substrate, an absent substrate and a properly placed substrate.

Step 426 is followed by step 428 of responding to the recovery related status of the substrate by a response unit.

Step 428 may include at least one of:
a. Requesting an execution of a manual unloading of the substrate from the handling station.
b. Requesting an execution of a substrate evaluation system controller unloading of the substrate from the handling station.
c. Instructing an execution of a substrate evaluation system controller unloading of the substrate from the handling station.
d. Sending an indication that a recovery of the substrate is irrelevant.
e. Stop a recovery process of the substrate.
f. Provide information about the exact location of the substrate.

Step 420 may be applied on more than a single substrate handling station. For example—the substrate evaluation system may include an additional substrate handling station. Step 422 may include illuminating one or more additional regions that are associated with the additional substrate handling station, during the execution of the substrate recovery related procedure. Step 424 may include generating additional sensed information that is indicative of the one or more additional regions. Step 424 may include apply the AI process on the sensed information and on the additional sensed information to determine the recovery related status of the substrate.

According to an embodiment the sensing unit is configured to acquire the sensed information regarding the one or more regions without an illumination of the one or more regions. For example—the sensing unit may be an ultrasonic sensor and/or a radar, and/or a thermal sensor that may generate the sensed information without an illumination unit.

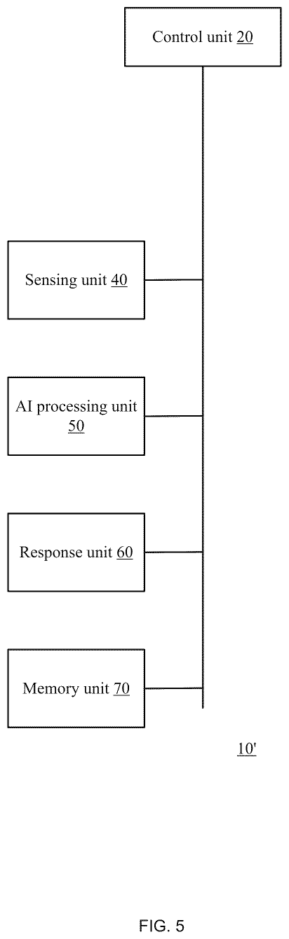

FIG. 5 illustrates an example of a substrate safety system 10′ that includes:
a. A control unit 20 that is configured to trigger a substrate recovery related procedure.
b. A sensing unit 40 that is configured to generate sensed information that is indicative of the one or more regions that are associated with a substrate handling station of a substrate evaluation system, during an execution of the substrate recovery related procedure.
c. An artificial intelligence (AI) processing unit 50 that is configured to apply an AI process on the sensed information to determine a recovery related status of the substrate.
d. A response unit 60 that is configured to respond to the recovery related status of the substrate.

FIG. 5 also illustrates a memory unit 70 configured to store instructions, and additionally or alternatively, information such as sensed information.

FIG. 4 illustrates an example of a method 400′ for enhancing a safety of a substrate.

Method 410 may start by step 410 of triggering, by a control unit, a substrate recovery related procedure.

Step 410 is followed by step 420′ of executing the substrate recovery related procedure.

Step 420′ includes step 424′, step 426 and step 428.

Step 424′ include of generating, by a sensing unit, sensed information that is indicative of the one or more regions that are associated with the substrate handling station of the substrate evaluation system.

Step 424′ is followed by step 426 of applying, by an artificial intelligence (AI) processing unit, an AI process on the sensed information to determine a recovery related status of the substrate.

Step 426 is followed by step 428 of responding to the recovery related status of the substrate by a response unit.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any reference to the term “comprising” or “having” or “including” should be applied mutatis mutandis to “consisting” and/or should be applied mutatis mutandis to “consisting essentially of”.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also, for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A substrate safety system comprising:
a control unit configured to trigger a substrate recovery related procedure;
a sensing unit configured to generate sensed information that is indicative of one or more regions that are associated with a substrate handling station of a substrate evaluation system, during an execution of the substrate recovery related procedure;
an artificial intelligence (AI) processing unit configured to apply an AI process on the sensed information to determine a recovery related status of a substrate; and
a response unit configured to respond to the recovery related status of the substrate.

2. The substrate safety system according to claim 1 wherein the recovery related status of the substrate is selected between a broken substrate, a misplaced substrate, an absent substrate and a properly placed substrate.

3. The substrate safety system according to claim 1 wherein the response unit is configured to respond by requesting an execution of a manual unloading of the substrate from the substrate handling station.

4. The substrate safety system according to claim 1 wherein the response unit is configured to respond by requesting an execution of a substrate evaluation system controller unloading of the substrate from the handling station.

5. The substrate safety system according to claim 1 wherein the response unit is configured to respond by sending an indication that a recovery of the substrate is irrelevant.

6. The substrate safety system according to claim 1 wherein the AI processing unit is configured to apply a classification process to determine the substrate recovery related status.

7. The substrate safety system according to claim 6 wherein the AI processing unit is trained to apply the classification process based on one or more coverage parameters related to a coverage of each one of the one or more regions by the substrate.

8. The substrate safety system according to claim 1 further comprising an illumination unit that is configured to illuminate the one or more regions.

9. The substrate safety system according to claim 1 wherein the one or more regions are multiple regions and wherein the sensing unit comprises a plurality of sensors.

10. The substrate safety system according to claim 1 wherein the substrate evaluation system comprises an additional substrate handling station; wherein the sensing unit is configured to generate additional sensed information that is indicative of one or more additional regions that are associated with the additional substrate handling station; and wherein the AI processing unit is configured to apply the AI process on the sensed information and on the additional sensed information to determine the recovery related status of the substrate.

11. A method for enhancing a safety of a substrate, the method comprises:
triggering, by a control unit, a substrate recovery related procedure;
generating, by a sensing unit and during an execution of the substrate recovery related procedure, sensed information that is indicative of one or more regions that are associated with a substrate handling station of a substrate evaluation system;
applying, by an artificial intelligence (AI) processing unit, an AI process on the sensed information to determine a recovery related status of the substrate; and
responding to the recovery related status of the substrate by a response unit.

12. The method according to claim 11 wherein the recovery related status of the substrate is selected between a broken substrate, a misplaced substrate, an absent substrate and a properly placed substrate.

13. The method according to claim 11 wherein the responding comprises requesting an execution of a manual unloading of the substrate from the substrate handling station.

14. The method according to claim 11 wherein the responding comprises requesting an execution of a substrate evaluation system controller unloading of the substrate from the handling station.

15. The method according to claim 11 wherein the responding comprises sending an indication that a recovery of the substrate is irrelevant.

16. The method according to claim 11 wherein the applying of the AI process comprises applying a classification process to determine the substrate recovery related status.

17. The method according to claim 16 wherein the AI processing unit is trained to apply the classification process based on one or more coverage parameters related to a coverage of each one of the one or more regions by the substrate.

18. The method according to claim 11 further comprising illuminating, by an illumination unit, the one or more regions.

19. The method according to claim 11 wherein the one or more regions are multiple regions and wherein the sensing unit comprises a plurality of sensors.

20. A non-transitory computer readable medium for enhancing a safety of a substrate, the non-transitory computer readable medium stores instructions that once executed by substrate safety system, cause the substrate safety system to:
trigger, by a control unit of the substrate safety system, a substrate recovery related procedure;
generate, by a sensing unit of the substrate safety system, sensed information that is indicative of one or more regions that are associated with a substrate handling station of a substrate evaluation system;
apply, by an artificial intelligence (AI) processing unit of the substrate safety system, an AI process on the sensed information to determine a recovery related status of the substrate; and
respond to the recovery related status of the substrate by a response unit of the substrate safety system.
